(19) United States
(12) Patent Application Publication
(10) Pub. No.: US 2022/0336332 A1
(43) Pub. Date: Oct. 20, 2022

(54) CONDUCTIVE STRUCTURE, PACKAGE STRUCTURE AND METHOD FOR MANUFACTURING THE SAME

(71) Applicant: Advanced Semiconductor Engineering, Inc., Kaohsiung (TW)

(72) Inventors: You-Lung YEN, Taoyuan (TW); Bernd Karl APPELT, Holly Springs, NC (US)

(73) Assignee: Advanced Semiconductor Engineering, Inc., Kaohsiung (TW)

(21) Appl. No.: 17/233,294

(22) Filed: Apr. 16, 2021

(51) Int. Cl. H01L 23/498; H01L 23/31; H01L 23/053; H01L 21/48; H01L 21/56

(52) U.S. Cl. CPC H01L 23/49811; H01L 23/3121; H01L 23/053; H01L 21/4853; H01L 21/56

(57) ABSTRACT

A conductive structure, a package structure and a method for manufacturing the same are provided. The conductive structure includes a main portion, a first electrical contact, a second electrical contact, a first post and a second post. The main portion has a first surface and a second surface opposite to the first surface. The first electrical contact is disposed adjacent to the first surface of the main portion. The second electrical contact is disposed adjacent to the second surface of the main portion and electrically connected to the first electrical contact. The first post is electrically connected to the first electrical contact. The second post is electrically connected to the second electrical contact.

### BACKGROUND

### 1. Field of the Disclosure

The present disclosure relates to a conductive structure including posts on different sides, and a package structure including the conductive structure, and to a method for manufacturing the same.

### 2. Description of the Related Art

Package-on-package (PoP) structure includes more than two packages stacked on one another vertically. One of the packages (i.e., a bottom package) includes a logic chip, and another of the packages (i.e., a top package) includes a memory chip. As compared with a structure that the packages are disposed side by side, such PoP structure occupies less footprint on a printed circuit board (PCB), and the stacked packages can electrically connect each other directly to improve electrical performance. Thus, the PoP structure is a desired solution for three dimensional package. However, the electrical interconnection between the stacked packages is a critical issue.

### SUMMARY

In some embodiments, a conductive structure includes a main portion, a first electrical contact, a second electrical contact, a first post and a second post. The main portion has a first surface and a second surface opposite to the first surface. The first electrical contact is disposed adjacent to the first surface of the main portion. The second electrical contact is disposed adjacent to the second surface of the main portion and electrically connected to the first electrical contact. The first post is electrically connected to the first electrical contact. The second post is electrically connected to the second electrical contact.

In some embodiments, a package structure includes a substrate, a conductive structure, an electronic device and an encapsulant. The conductive structure is attached to the substrate. The conductive structure includes a main portion, a first electrical contact, a second electrical contact, a first post and a second post. The main portion has a first surface and a second surface opposite to the first surface. The first electrical contact is disposed adjacent to the first surface of the main portion. The second electrical contact is disposed adjacent to the second surface of the main portion and electrically connected to the first electrical contact. The first post is electrically connected to the first electrical contact. The second post is electrically connected to the second electrical contact and the substrate. The electronic device is electrically connected to the substrate or the conductive structure. The encapsulant covers the substrate, the conductive structure and the electronic device.

In some embodiments, a method for manufacturing a package structure includes: (a) providing a conductive structure, wherein the conductive structure comprises a main portion, a first post and a second post, the first post is disposed adjacent to a first surface of the main portion, the second post is disposed adjacent to a second surface of the main portion and electrically connected to the first post; (b) electrically connecting the second post to a substrate; (c) electrically connecting an electronic device to the substrate or the conductive structure; and (d) forming an encapsulant to cover the substrate, the conductive structure and the electronic device.

### BRIEF DESCRIPTION OF THE DRAWINGS

Aspects of some embodiments of the present disclosure are readily understood from the following detailed description when read with the accompanying figures. It is noted that various structures may not necessarily be drawn to scale, and dimensions of the various structures may be arbitrarily increased or reduced for clarity of discussion.

FIG. 1 illustrates a cross-sectional view of a conductive structure according to some embodiments of the present disclosure.

FIG. 2 illustrates a cross-sectional view of a conductive structure according to some embodiments of the present disclosure.

FIG. 3 illustrates a cross-sectional view of a semiconductor package structure according to some embodiments of the present disclosure.

FIG. 4 illustrates a cross-sectional view of a semiconductor package structure according to some embodiments of the present disclosure.

FIG. 5 illustrates a cross-sectional view of a semiconductor package structure according to some embodiments of the present disclosure.

FIG. 6 illustrates a cross-sectional view of a semiconductor package structure according to some embodiments of the present disclosure.

FIG. 7 illustrates a cross-sectional view of a semiconductor package structure according to some embodiments of the present disclosure.

FIG. 8 illustrates a cross-sectional view of a semiconductor package structure according to some embodiments of the present disclosure.

FIG. 9 illustrates a cross-sectional view of a semiconductor package structure according to some embodiments of the present disclosure.

FIG. 10 illustrates a cross-sectional view of a semiconductor package structure according to some embodiments of the present disclosure.

FIG. 11 illustrates a cross-sectional view of a semiconductor package structure according to some embodiments of the present disclosure.

FIG. 12 illustrates a cross-sectional view of a semiconductor package structure according to some embodiments of the present disclosure.

FIG. 13 illustrates a cross-sectional view of a semiconductor package structure according to some embodiments of the present disclosure.

FIG. 14 illustrates a cross-sectional view of a semiconductor package structure according to some embodiments of the present disclosure.

FIG. 15 illustrates a cross-sectional view of a semiconductor package structure according to some embodiments of the present disclosure.

FIG. 16 illustrates a cross-sectional view of a semiconductor package structure according to some embodiments of the present disclosure.

FIG. 17 illustrates a cross-sectional view of a semiconductor package structure according to some embodiments of the present disclosure.

FIG. 18 illustrates a cross-sectional view of a semiconductor package structure according to some embodiments of the present disclosure.

FIG. 19 illustrates a cross-sectional view of a semiconductor package structure according to some embodiments of the present disclosure.

FIG. 20 illustrates one or more stages of an example of a method for manufacturing a semiconductor package structure according to some embodiments of the present disclosure.

FIG. 21 illustrates one or more stages of an example of a method for manufacturing a semiconductor package structure according to some embodiments of the present disclosure.

FIG. 22 illustrates one or more stages of an example of a method for manufacturing a semiconductor package structure according to some embodiments of the present disclosure.

FIG. 23 illustrates one or more stages of an example of a method for manufacturing a semiconductor package structure according to some embodiments of the present disclosure.

FIG. 24 illustrates one or more stages of an example of a method for manufacturing a semiconductor package structure according to some embodiments of the present disclosure.

FIG. 25 illustrates one or more stages of an example of a method for manufacturing a semiconductor package structure according to some embodiments of the present disclosure.

FIG. 26 illustrates one or more stages of an example of a method for manufacturing a semiconductor package structure according to some embodiments of the present disclosure.

FIG. 27 illustrates one or more stages of an example of a method for manufacturing a semiconductor package structure according to some embodiments of the present disclosure.

### DETAILED DESCRIPTION

Common reference numerals are used throughout the drawings and the detailed description to indicate the same or similar components. Embodiments of the present disclosure will be readily understood from the following detailed description taken in conjunction with the accompanying drawings.

The following disclosure provides many different embodiments, or examples, for implementing different features of the provided subject matter. Specific examples of components and arrangements are described below to explain certain aspects of the present disclosure. These are, of course, merely examples and are not intended to be limiting. For example, the formation of a first feature over or on a second feature in the description that follows may include embodiments in which the first and second features are formed or disposed in direct contact, and may also include embodiments in which additional features may be formed or disposed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

In a comparative stacked package structure, two substrates are physically connected and electrically connected to each other through a plurality of solder balls; however, the solder balls may contact with each other and cause a short circuit readily, and the pitch between the solder balls may not be reduced efficiently. In another comparative stacked package structure, two substrates are physically connected and electrically connected to each other through a plurality of single tall copper pillars; however, it is difficult to grow such tall and thin pillars. In another comparative stacked package structure, two substrates are physically connected and electrically connected to each other through a plurality of through mold vias (TMVs); however, it needs complicated processes including, for example, forming a plurality of through holes in a molding compound by laser drill, and then plate or fill metal material in the through holes of the molding compound. Thus, a yield rate is relatively low.

At least some embodiments of the present disclosure provide for a conductive structure which includes double sided pillars or posts. Thus, the pitch between the pillars or posts is shortened, and the yield rate is increased. In addition to Package-on-package (PoP) structure, such conductive structure may be also used in PoM (Package-on-Module) structure, MoM (Module-on-Module) structure and stacked SiP (System in Package) structure.

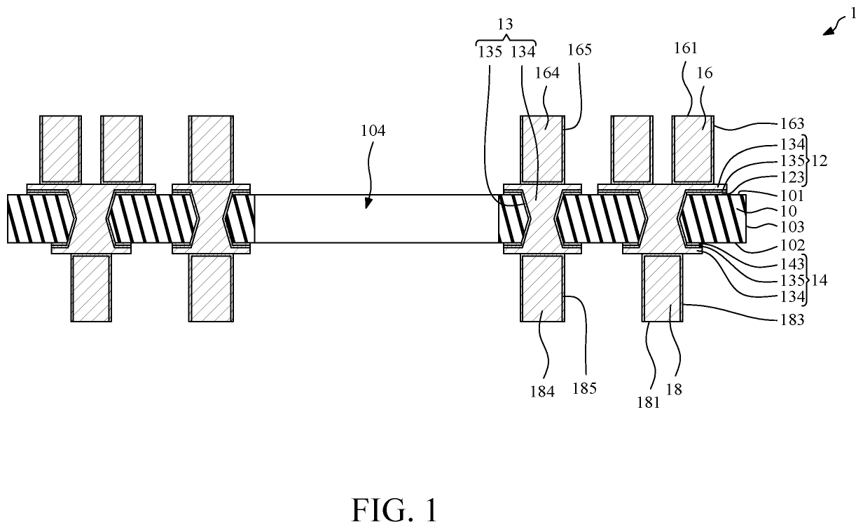

FIG. 1 illustrates a cross-sectional view of a conductive structure 1 according to some embodiments of the present disclosure. The conductive structure 1 may include a main portion 10, at least one first electrical contact 12, at least one second electrical contact 14, at least one conductive through via 13, at least one first post 16 and at least one second post 18.

The main portion 10 may be an interposer or a substrate, and may include organic material, glass or silicon. For example, the main portion 10 may include a homogeneous material. The main portion 10 may have a first surface 101 (e.g., a top surface), a second surface 102 (e.g., a bottom surface) opposite to the first surface 101 and an outer lateral surface 103 extending between the first surface 101 and the second surface 102. As shown in FIG. 1, the main portion 10 may define a through hole 104 extending through the main portion 10. Thus, the through hole 104 may extend between the first surface 101 and the second surface 102.

The conductive through via 13 may extend through the main portion 10, and may include a seed layer 135 and a conductive material 134 disposed on the main portion 10 sequently. In some embodiments, the seed layer 135 may include a titanium layer and/or a copper layer, and may be formed by chemical vapor deposition (CVD). The conductive material 134 may include pure metal such as copper, and may be formed by plating. In some embodiments, a cross section of the conductive through via 13 may be in a shape of sandglass, and may include a neck portion. That is, a width of an upper portion of the conductive through via 13 and a width of a lower portion of the conductive through via 13 is greater than a width of a middle portion of the conductive through via 13. However, in other embodiments, the conductive through via 13 may be in a shape of a cylinder or a taper.

The first electrical contact 12 may be disposed adjacent to or disposed on the first surface 101 of the main portion 10. In some embodiments, the first electrical contact 12 may be a pad or a trace, and may be included in a patterned circuit layer such as a fan-out circuit layer or a redistribution layer. As shown in FIG. 1, the first electrical contact 12 may include a base layer 123, a seed layer 135 and a conductive material 134 disposed on the first surface 101 of the main portion 10 sequently. The base layer 123 may be a copper foil, and may be formed by lamination. The seed layer 135 may include a titanium layer and/or a copper layer, and may be formed by chemical vapor deposition (CVD). The conductive material 134 may include pure metal such as copper, and may be formed by plating.

The second electrical contact 14 may be disposed adjacent to or disposed on the second surface 102 of the main portion 10. In some embodiments, the second electrical contact 14 may be a pad or a trace, and may be included in a patterned circuit layer such as a fan-out circuit layer or a redistribution layer. As shown in FIG. 1, a structure of the second electrical contact 14 may be same as a structure of the first electrical contact 12. Thus, the second electrical contact 14 may also include a base layer 143, a seed layer 135 and a conductive material 134 disposed on the second surface 102 of the main portion 10 sequently.

The second electrical contact 14 may be electrically connected to the first electrical contact 12 through the conductive through via 13. Thus, the conductive through via 13 is used for electrically connecting the first electrical contact 12 and the second electrical contact 14. In some embodiments, the second electrical contact 14, the first electrical contact 12 and the conductive through via 13 are formed integrally and concurrently. As shown in FIG. 1, the seed layer 135 of the first electrical contact 12, the seed layer 135 of the conductive through via 13 and the seed layer 135 of the second electrical contact 14 are the same layer and are formed concurrently. Further, the conductive material 134 of the first electrical contact 12, the conductive material 134 of the conductive through via 13 and the conductive material 134 of the second electrical contact 14 are the same layer and are formed concurrently.

The first post 16 may be physically connected and/or electrically connected to the first electrical contact 12. The first post 16 may be a pillar, a bump or a stud that is stand on and contact the first electrical contact 12. A height of the first post 16 may be greater than a thickness of the first electrical contact 12. The first post 16 may include a conductive material 164 and a seed layer 165 surrounding and contacting the conductive material 164. The conductive material 164 may include a pure material (e.g., pure metal such as copper), and may be formed by plating. The seed layer 165 may include a titanium layer and/or a copper layer, and may be formed by chemical vapor deposition (CVD). In addition, the first post 16 may have an end surface 161 and a peripheral side surface 163. The end surfaces 161 of all of the first posts 16 may be substantially coplanar with each other since they may be formed concurrently by grinding. The peripheral side surface 163 of the first post 16 may be perpendicular to the first surface 101 of the main portion 10 since the first post 16 may be formed by photolithography technique and plating process. In some embodiments, the height of the first post 16 may be less than 150 μm, such as less than or equal to 100 μm, or less than or equal to 50 μm. A diameter of the first post 16 may be in a range of 30 μm to 40 μm.

The second post 18 may be physically connected and/or electrically connected to the second electrical contact 14. The second post 18 may be a pillar, a bump or a stud that is stand on and contact the second electrical contact 14. A height of the second post 18 may be greater than a thickness of the second electrical contact 14. The second post 18 may include a conductive material 184 and a seed layer 185 surrounding and contacting the conductive material 184. The conductive material 184 may include a pure material (e.g., pure metal such as copper), and may be formed by plating. The seed layer 185 may include a titanium layer and/or a copper layer, and may be formed by chemical vapor deposition (CVD). In addition, the second post 18 may have an end surface 181 and a peripheral side surface 183. The end surfaces 181 of all of the second posts 18 may be substantially coplanar with each other since they may be formed concurrently by grinding. The peripheral side surface 183 of the second post 18 may be perpendicular to the second surface 102 of the main portion 10 since the second post 18 may be formed by photolithography technique and plating process. In some embodiments, the height of the second post 18 may be less than 150 μm, such as less than or equal to 100 μm, or less than or equal to 50 μm. A diameter of the second post 18 may be in a range of 30 μm to 40 μm.

In some embodiments, the central axis of the first post 16 may be aligned with the central axis of the second post 18. However, in other embodiments, the central axis of the first post 16 may be misaligned with the central axis of the second post 18. That is, the central axis of the first post 16 may be shifted from the central axis of the second post 18.

In the embodiment illustrated in FIG. 1, the first post 16 and the second post 18 are disposed on two sides of the main portion 10 for external connection, thus, the height of the first post 16 and the height of the second post 18 may be reduced, and the pitch between the first posts 16 and the pitch between the second posts 18 may be shortened. In addition, the peripheral side surface 163 of the first post 16 and the peripheral side surface 183 of the second post 18 may be perpendicular to the first surface 101 and the second surface 102 of the main portion 10, respectively; thus, a short circuit between the first posts 16 and between the second posts 18 may be avoided, and the yield rate may be improved.

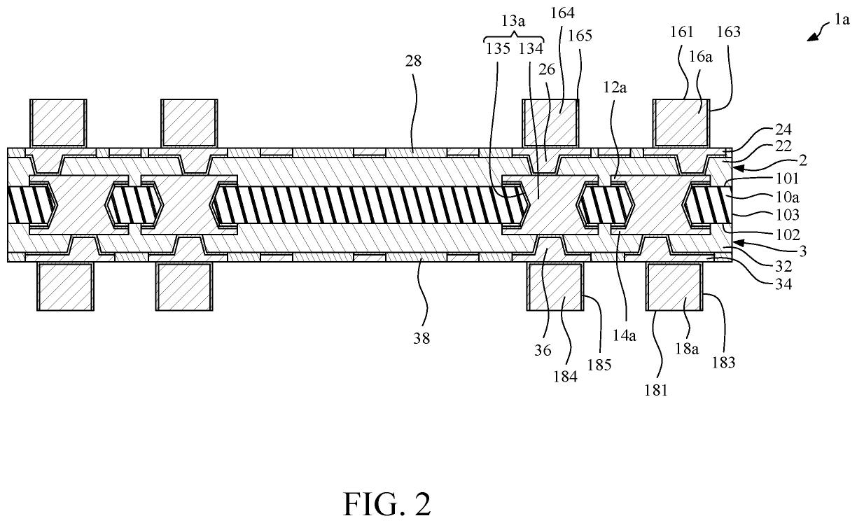

FIG. 2 illustrates a cross-sectional view of a conductive structure 1a according to some embodiments of the present disclosure. The conductive structure 1a of FIG. 2 may be similar to the conductive structure 1 of FIG. 1 except that the through hole 104 is omitted and a first redistribution structure 2 and a second redistribution structure 3 are further included. As shown in FIG. 2, the conductive structure 1a may include a main portion 10a, at least one first electrical contact 12a, at least one second electrical contact 14a, at least one conductive through via 13a, the first redistribution structure 2, the second redistribution structure 3, at least one first post 16a and at least one second post 18a.

The main portion 10a, the first electrical contact 12a, the second electrical contact 14a and the conductive through via 13a of the conductive structure 1a of FIG. 2 may be similar to or the same as the main portion 10, the first electrical contact 12, the second electrical contact 14 and the conductive through via 13 conductive structure 1 of FIG. 1, respectively. The first redistribution structure 2 may be disposed on the first surface 101 of the main portion 10 and may cover the first electrical contact 12a. The first redistribution structure 2 may include a first dielectric layer 22, a first circuit layer 24, at least one first inner via 26 and a first protection layer 28. The first dielectric layer 22 may cover and contact the first electrical contact 12a and the first surface 101 of the main portion 10. The first dielectric layer 22 may include, or be formed from, a photoresist layer, a cured photo sensitive material, a cured photoimageable dielectric (PID) material such as epoxy or polyimide (PI) including photoinitiators, or a combination of two or more thereof. The first circuit layer 24 may be a patterned circuit layer such as a fan-out circuit layer or a redistribution layer. The first circuit layer 24 may be disposed on the first dielectric layer 22, and may be electrically connected to the first electrical contact 12a through the first inner via 26. The first circuit layer 24 and the first inner via 26 may be formed integrally and concurrently.

The first protection layer 28 (e.g., a solder resist layer) may be disposed on the first dielectric layer 22, and may contact and protect the first circuit layer 24. The first post 16a of the conductive structure 1a of FIG. 2 may be similar to or the same as the first post 16 of FIG. 1. The first post 16a stands on and contacts the first circuit layer 24. Thus, the first post 16a is electrically connected to the first electrical contact 12a through the first redistribution structure 2.

The second redistribution structure 3 may be disposed on the second surface 102 of the main portion 10 and may cover the second electrical contact 14a. The second redistribution structure 3 may include a second dielectric layer 32, a second circuit layer 34, at least one second inner via 36 and a second protection layer 38. The second dielectric layer 32 may cover and contact the second electrical contact 14a and the second surface 102 of the main portion 10. The second dielectric layer 32 may include, or be formed from, a photoresist layer, a cured photo sensitive material, a cured photoimageable dielectric (PID) material such as epoxy or polyimide (PI) including photoinitiators, or a combination of two or more thereof. The second circuit layer 34 may be a patterned circuit layer such as a fan-out circuit layer or a redistribution layer. The second circuit layer 34 may be disposed on the second dielectric layer 32, and may be electrically connected to the second electrical contact 14a through the second inner via 36. The second circuit layer 34 and the second inner via 36 may be formed integrally and concurrently.

The second protection layer 38 (e.g., a solder resist layer) may be disposed on the second dielectric layer 32, and may contact and protect the second circuit layer 34. The second post 18a of the conductive structure 1a of FIG. 2 may be similar to or the same as the second post 18 of FIG. 1. The second post 18a stands on and contacts the second circuit layer 34. Thus, the second post 18a is electrically connected to the second electrical contact 14a through the second redistribution structure 3.

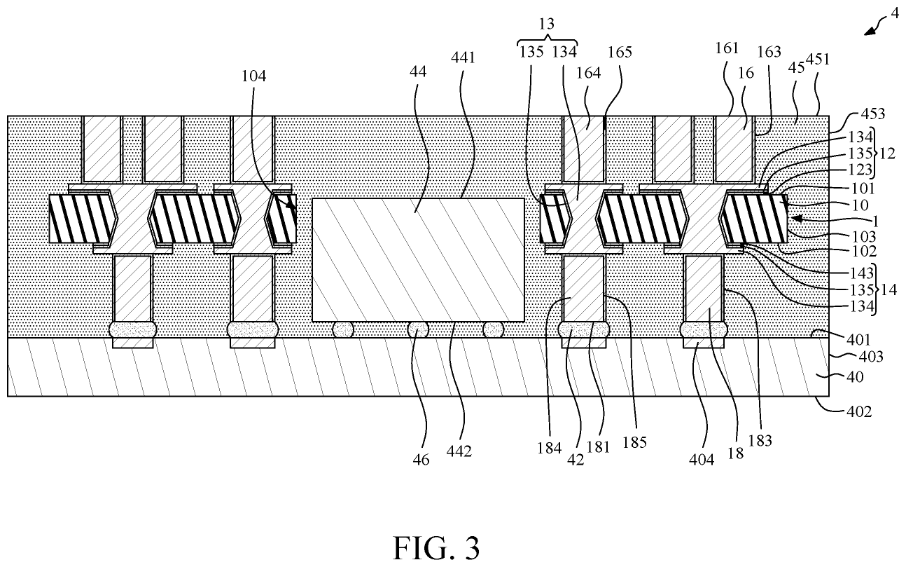

FIG. 3 illustrates a cross-sectional view of a semiconductor package structure 4 according to some embodiments of the present disclosure. The semiconductor package structure 4 includes a substrate 40, a conductive structure 1, an electronic device 44 and an encapsulant 45. The substrate 40 may have a first surface 401 (e.g., a top surface), a second surface 402 (e.g., a bottom surface) opposite to the first surface 401 and an outer lateral surface 403 extending between the first surface 401 and the second surface 402. As shown in FIG. 3, the substrate 40 may include a plurality of pads 404 disposed adjacent to the first surface 401 of the substrate 40. The conductive structure 1 of FIG. 3 may be similar to or the same as the conductive structure 1 of FIG. 1, and may be attached to the substrate 40. In some embodiments, the end surfaces 181 of the second posts 18 may be attached to the pads 404 of the substrate 40 through a plurality of solder bumps 42.

The electronic device 44 may be a semiconductor chip, a semiconductor die or a passive component, and may have a first surface 441 (e.g., a top surface) and a second surface 442 (e.g., a bottom surface) opposite to the first surface 441. The second surface 442 may be an active surface, and the first surface 441 may be a backside surface. The second surface 442 of the electronic device 44 may be electrically connected to the substrate 40 through the solder materials 46. Thus, the electronic device 44 is attached to the substrate 40 through flip-chip bonding. In addition, a portion of the electronic device 44 is located in the through hole 104 of the conductive structure 1. That is, a width of the electronic device 44 may be less than a width of the through hole 104 of the conductive structure 1.

The encapsulant 45 (e.g., a molding compound) may cover the first surface 401 of the substrate 40, the conductive structure 1 and the electronic device 44. The encapsulant 45 may have a first surface 451 (e.g., a top surface) and an outer lateral surface 453. The end surfaces 161 of the first posts 16 may be substantially coplanar with the first surface 451 of the encapsulant 45. A portion of the encapsulant 45 may cover the outer lateral surface 103 of the main portion 10. Thus, the outer lateral surface 453 of the encapsulant 45 may be spaced apart from the outer lateral surface 103 of the main portion 10. Further, the outer lateral surface 453 of the encapsulant 45 may be substantially coplanar with the outer lateral surface 403 of the substrate 40.

As shown in FIG. 3, the electronic device 44 is disposed in the through hole 104 of the conductive structure 1, thus, the total thickness of the semiconductor package structure 4 may be reduced. In addition, the mold clearance (i.e., a distance between the first surface 441 of the electronic device 44 and the first surface 451 of the encapsulant 45) is relatively large, thus, mold void may be reduced, and the yield rate of the semiconductor package structure 4 may be improved. Further, the electronic device 44 may have a relatively large thickness; that is, a thick electronic device 44 may be used in the semiconductor package structure 4 without increasing the thickness of the total thickness of the semiconductor package structure 4.

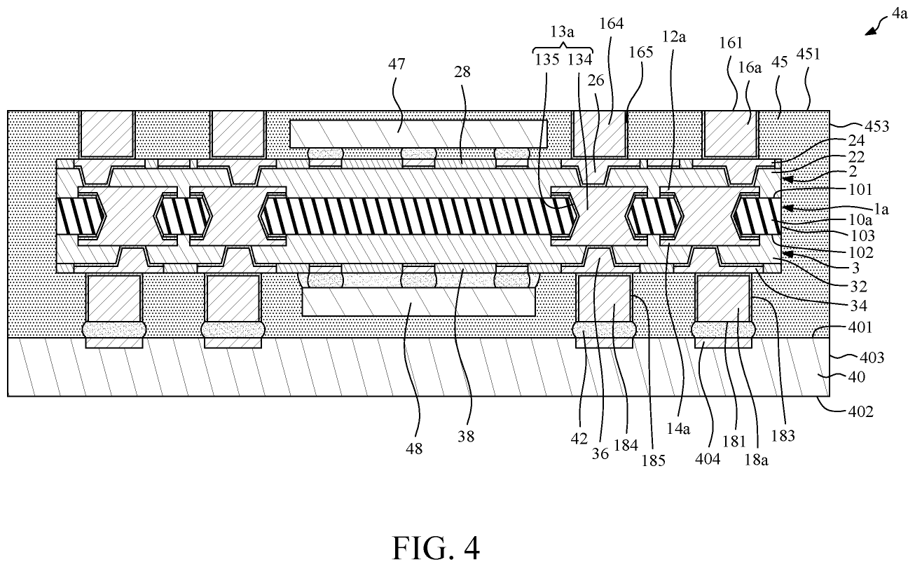

FIG. 4 illustrates a cross-sectional view of a semiconductor package structure 4a according to some embodiments of the present disclosure. The semiconductor package structure 4a includes a substrate 40, a conductive structure 1a, an upper electronic device 47, a lower electronic device 48 and an encapsulant 45. The substrate 40 of FIG. 4 may be similar to or the same as the substrate 40 of FIG. 3. The conductive structure 1a of FIG. 4 may be similar to or the same as the conductive structure 1a of FIG. 2, and may be attached to the substrate 40. In some embodiments, the end surfaces 181 of the second posts 18a may be attached to the pads 404 of the substrate 40 through a plurality of solder bumps 42.

The upper electronic device 47 may be a semiconductor chip, a semiconductor die or a passive component, and may be attached to and electrically connected to the first circuit layer 24 of the first redistribution structure 2 of the conductive structure 1a through flip-chip bonding. However, in other embodiments, the upper electronic device 47 may be electrically connected to the first circuit layer 24 of the first redistribution structure 2 of the conductive structure 1a through wire bonding. In addition, the lower electronic device 48 may be a semiconductor chip, a semiconductor die or a passive component, and may be attached to and electrically connected to the second circuit layer 34 of the second redistribution structure 3 of the conductive structure 1a through flip-chip bonding. However, in other embodiments, the lower electronic device 48 may be electrically connected to the second circuit layer 34 of the second redistribution structure 3 of the conductive structure 1a through wire bonding. The upper electronic device 47 and the lower electronic device 48 may have same or different function.

The encapsulant 45 (e.g., a molding compound) may cover the first surface 401 of the substrate 40, the conductive structure 1a, the upper electronic device 47 and the lower electronic device 48. The encapsulant 45 may have a first surface 451 (e.g., a top surface) and an outer lateral surface 453. The end surfaces 161 of the first posts 16a may be substantially coplanar with the first surface 451 of the encapsulant 45. A portion of the encapsulant 45 may cover the outer lateral surface 103 of the main portion 10a. Thus, the outer lateral surface 453 of the encapsulant 45 may be spaced apart from the outer lateral surface 103 of the main portion 10a. Further, the outer lateral surface 453 of the encapsulant 45 may be substantially coplanar with the outer lateral surface 403 of the substrate 40.

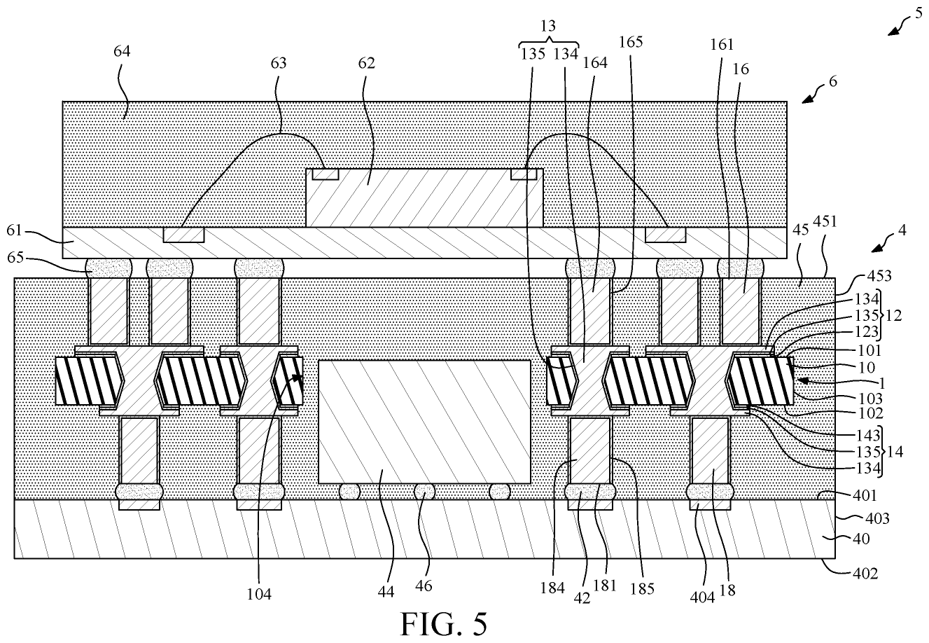

FIG. 5 illustrates a cross-sectional view of a semiconductor package structure 5 according to some embodiments of the present disclosure. The semiconductor package structure 5 includes a semiconductor package structure 4 (i.e., a bottom package structure) and a top element 6. The semiconductor package structure 4 of FIG. 5 may be similar to or the same as the semiconductor package structure 4 of FIG. 3. The top element 6 is disposed on the first post 16 of the semiconductor package structure 4. In some embodiments, the top element 6 may be a package structure that includes a substrate 61, an electronic device 62 (e.g., a semiconductor die or a semiconductor chip), a plurality of conductive wires 63 and an encapsulant 64. A backside surface of the electronic device 62 is attached or adhered to the substrate 61, and an active surface of the electronic device 62 is electrically connected to the substrate 61 through the conductive wires 63. The encapsulant 64 (e.g., a molding compound) is disposed on the substrate 61 to cover and encapsulate the electronic device 62 and the conductive wires 63. As shown in FIG. 5, the substrate 61 of the top element 6 is attached to and electrically connected to the end surface 161 of the first post 16 of the conductive structure 1 of the semiconductor package structure 4 through the solder material 65.

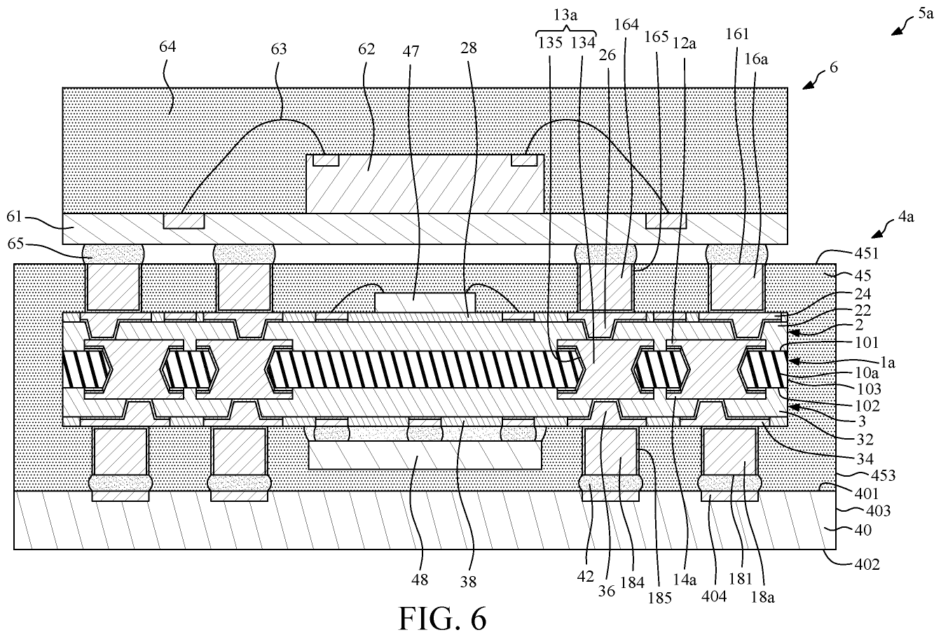

FIG. 6 illustrates a cross-sectional view of a semiconductor package structure 5a according to some embodiments of the present disclosure. The semiconductor package structure 5a includes a semiconductor package structure 4a (i.e., a bottom package structure) and a top element 6. The semiconductor package structure 4a of FIG. 6 may be similar to or the same as the semiconductor package structure 4a of FIG. 4. In some embodiments, the upper electronic device 47 may be electrically connected to the first circuit layer 24 of the first redistribution structure 2 of the conductive structure 1a through wire bonding. In addition, the top element 6 is disposed on the first post 16a of the semiconductor package structure 4a. The top element 6 of FIG. 6 may be similar to or the same as the top element 6 of FIG. 5. As shown in FIG. 6, the substrate 61 of the top element 6 is attached to and electrically connected to the end surface 161 of the first post 16a of the conductive structure 1a of the semiconductor package structure 4a through the solder material 65.

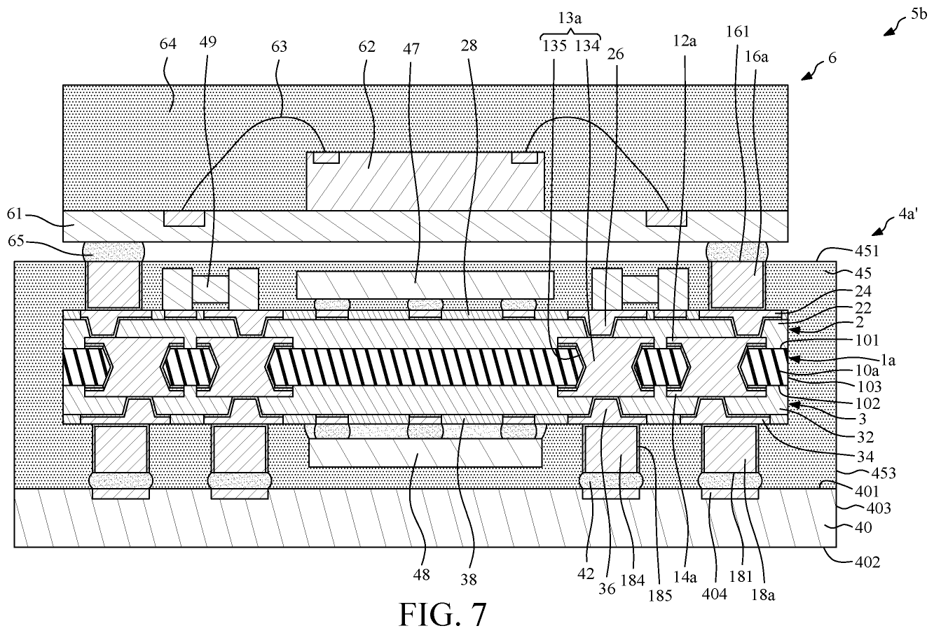

FIG. 7 illustrates a cross-sectional view of a semiconductor package structure 5b according to some embodiments of the present disclosure. The semiconductor package structure 5b of FIG. 7 is similar to the semiconductor package structure 5a of FIG. 6, except that the semiconductor package structure 4a′ of FIG. 7 further includes at least one passive component 49 (e.g., a resistor) attached and electrically connected to the first circuit layer 24 of the first redistribution structure 2 of the conductive structure 1a.

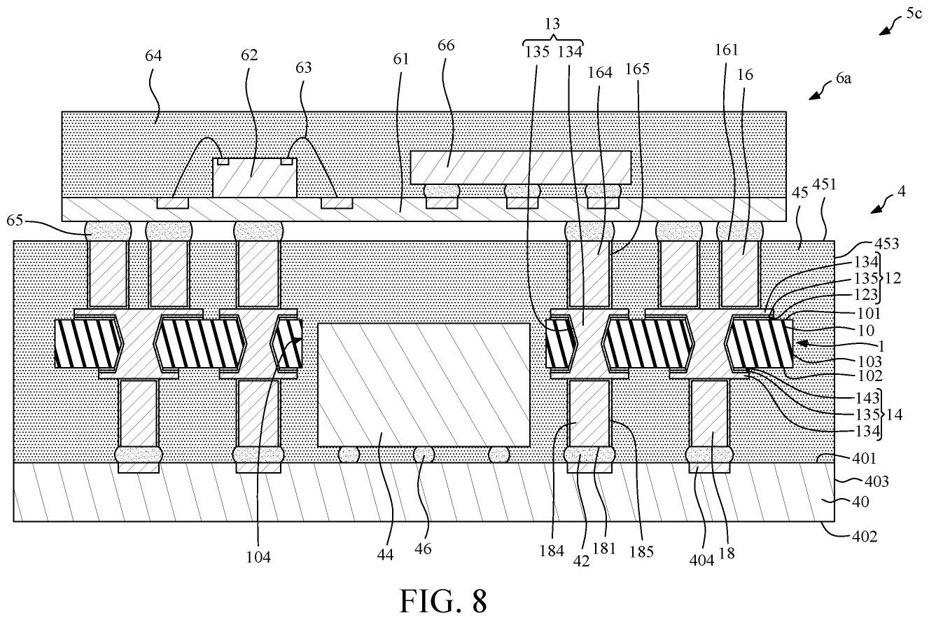

FIG. 8 illustrates a cross-sectional view of a semiconductor package structure 5c according to some embodiments of the present disclosure. The semiconductor package structure 5c of FIG. 8 is similar to the semiconductor package structure 5 of FIG. 5, except that the top element 6a of FIG. 8 further includes an additional electronic device 66 (e.g., a semiconductor die or a semiconductor chip) electrically connected to the substrate 61 through flip-chip bonding. The electronic device 62 and the additional electronic device 66 may have same or different function. Thus, the top element 6a may be a module. For example, one of the electronic devices 62, 66 may be a semiconductor logic die such as a CPU (Central Processing Unit), a GPU (Graphics Processing Unit) or an AP (Application Processor), and the other one of the electronic devices 62, 66 may be a memory die.

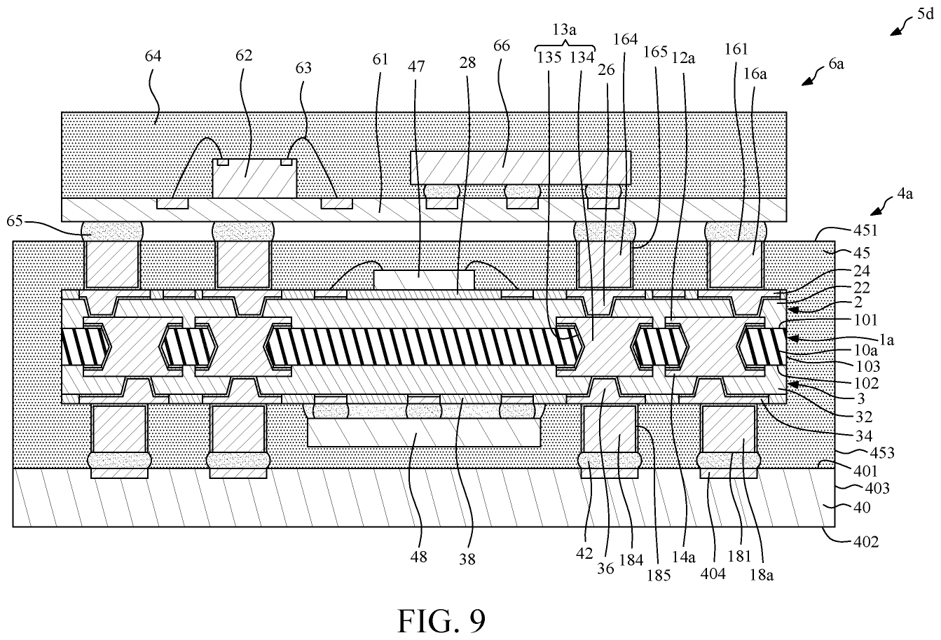

FIG. 9 illustrates a cross-sectional view of a semiconductor package structure 5d according to some embodiments of the present disclosure. The semiconductor package structure 5d of FIG. 9 is similar to the semiconductor package structure 5a of FIG. 6, except that the top element 6a of FIG. 9 further includes an additional electronic device 66 (e.g., a semiconductor die or a semiconductor chip) electrically connected to the substrate 61 through flip-chip bonding. The electronic device 62 and the additional electronic device 66 may have same or different function. Thus, the top element 6a may be a module.

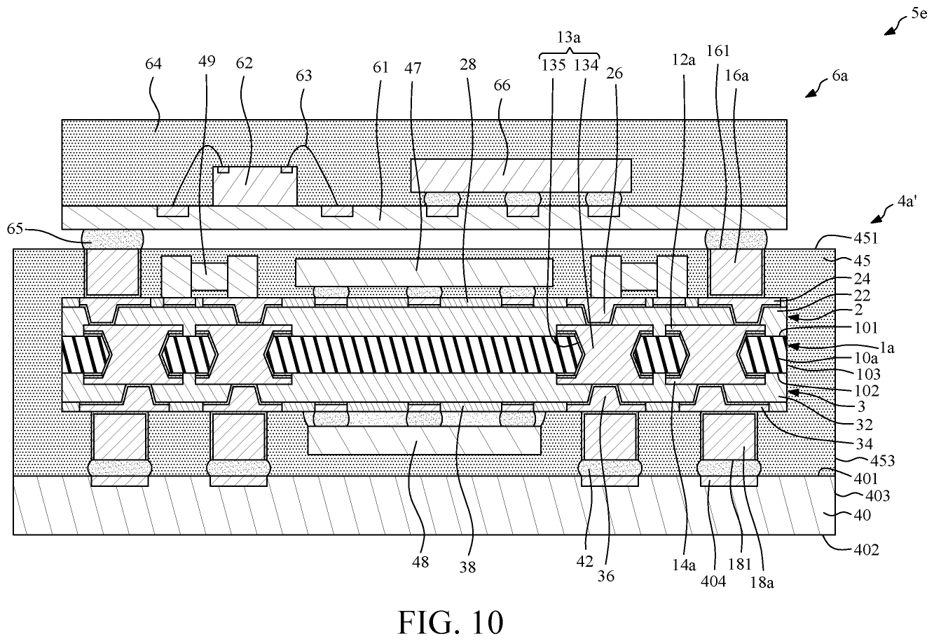

FIG. 10 illustrates a cross-sectional view of a semiconductor package structure 5e according to some embodiments of the present disclosure. The semiconductor package structure 5e of FIG. 10 is similar to the semiconductor package structure 5b of FIG. 7, except that the top element 6a of FIG. 10 further includes an additional electronic device 66 (e.g., a semiconductor die or a semiconductor chip) electrically connected to the substrate 61 through flip-chip bonding. The electronic device 62 and the additional electronic device 66 may have same or different function. Thus, the top element 6a may be a module.

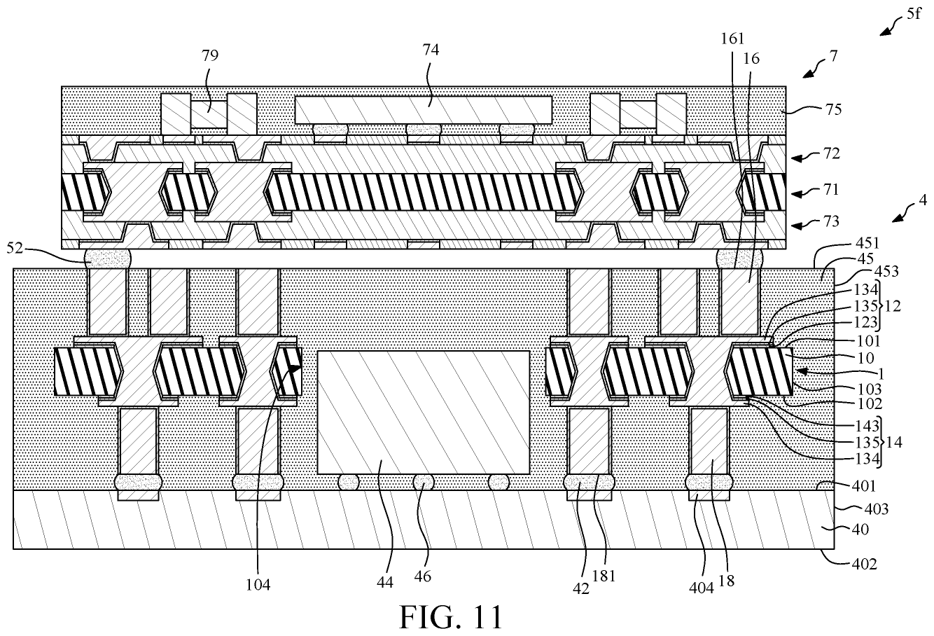

FIG. 11 illustrates a cross-sectional view of a semiconductor package structure 5f according to some embodiments of the present disclosure. The semiconductor package structure 5f includes a semiconductor package structure 4 (i.e., a bottom package structure) and a top element 7. The semiconductor package structure 4 of FIG. 11 may be similar to or the same as the semiconductor package structure 4 of FIG. 3. The top element 7 is disposed on the first post 16 of the semiconductor package structure 4.

In some embodiments, the top element 7 of FIG. 11 is similar to the semiconductor package structure 4a′ of FIG. 7, except that the first post 16a, the second post 18a, the lower electronic device 48 and the substrate 40 of the semiconductor package structure 4a′ of FIG. 7 are omitted. In some embodiments, the top element 7 may be a system-in package (SiP), and may include a main portion 71, at least one first electrical contact, at least one second electrical contact, at least one conductive through via, a first redistribution structure 72, a second redistribution structure 73, an electronic device 74, at least one passive component 79 and an encapsulant 75 that may be similar to or the same as the main portion 10a, the first electrical contact 12a, the second electrical contact 14a, the conductive through via 13a, the first redistribution structure 2, the second redistribution structure 3, the upper electronic device 47, the passive component 49 and the encapsulant 45 of the semiconductor package structure 4a′ of FIG. 7, respectively. As shown in FIG. 11, the second redistribution structure 73 of the top element 7 is attached to and electrically connected to the end surface 161 of the first post 16 of the conductive structure 1 of the semiconductor package structure 4 through the solder material 52.

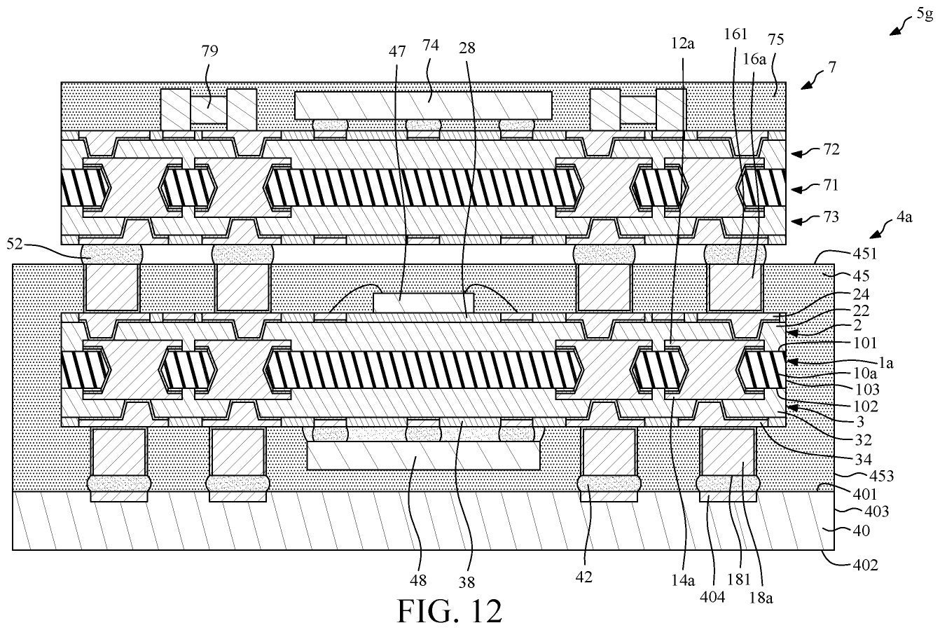

FIG. 12 illustrates a cross-sectional view of a semiconductor package structure 5g according to some embodiments of the present disclosure. The semiconductor package structure 5g includes a semiconductor package structure 4a and a top element 7. The semiconductor package structure 4a of FIG. 12 may be similar to or the same as the semiconductor package structure 4a of FIG. 6. The top element 7 is disposed on the first post 16a of the semiconductor package structure 4a. The top element 7 of FIG. 12 may be similar to or the same as the top element 7 of FIG. 11. As shown in FIG. 12, the second redistribution structure 73 of the top element 7 is attached to and electrically connected to the end surface 161 of the first post 16a of the conductive structure 1a of the semiconductor package structure 4a through the solder material 52.

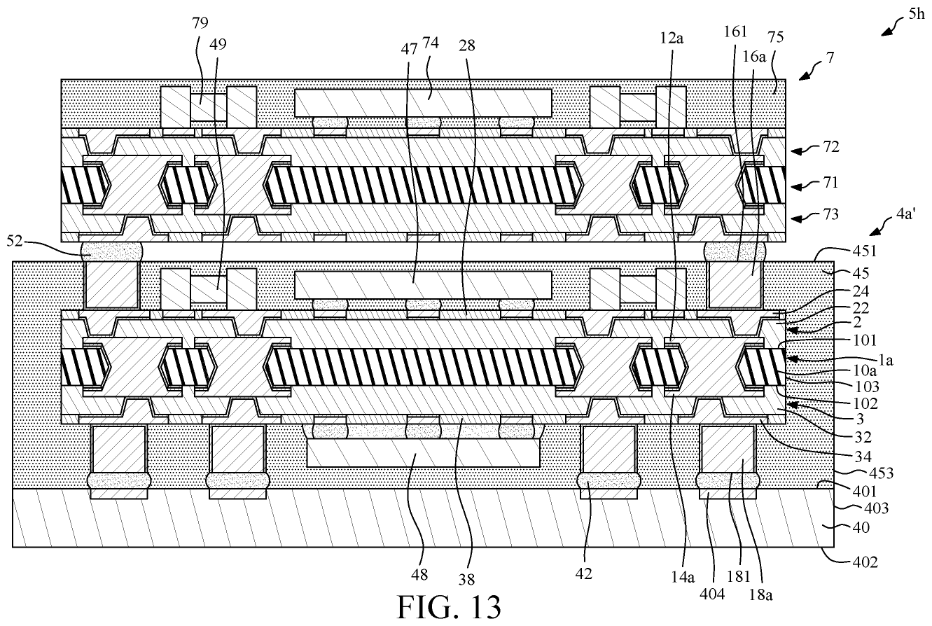

FIG. 13 illustrates a cross-sectional view of a semiconductor package structure 5h according to some embodiments of the present disclosure. The semiconductor package structure 5h of FIG. 13 is similar to the semiconductor package structure 5g of FIG. 12, except that the semiconductor package structure 4a′ of FIG. 13 further includes at least one passive component 49 (e.g., a resistor) attached and electrically connected to the first circuit layer 24 of the first redistribution structure 2 of the conductive structure 1a.

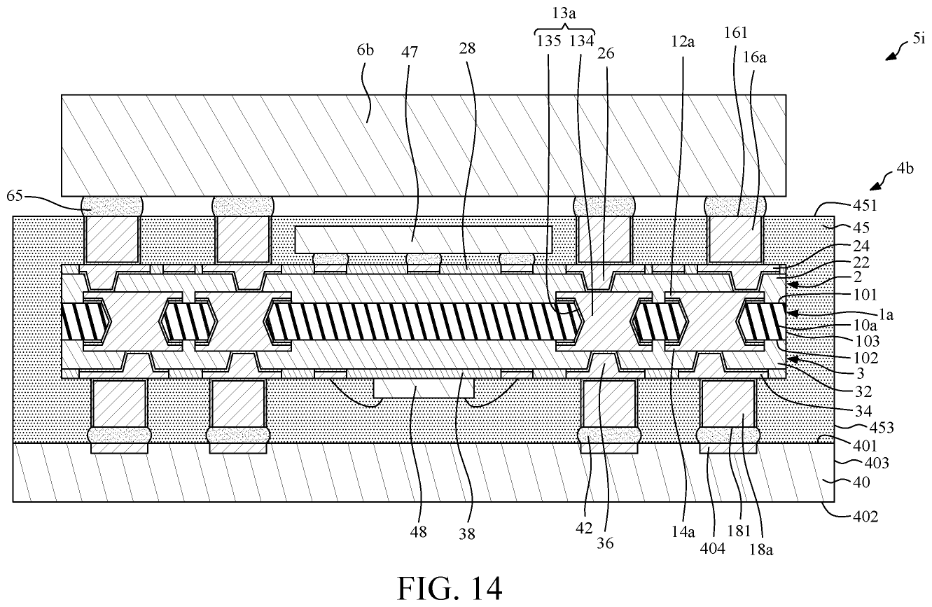

FIG. 14 illustrates a cross-sectional view of a semiconductor package structure 5i according to some embodiments of the present disclosure. The semiconductor package structure 5i includes a semiconductor package structure 4b (i.e., a bottom package structure) and a top element 6b. The semiconductor package structure 4b of FIG. 14 is similar to the semiconductor package structure 4a of FIG. 4, except that the lower electronic device 48 may be electrically connected to the second circuit layer 34 of the second redistribution structure 3 of the conductive structure 1a through wire bonding. The top element 6b of FIG. 14 may be disposed on and attached to the first post 16a of the conductive structure 1a of the semiconductor package structure 4b. In some embodiments, the top element 6b may be a semiconductor die or a semiconductor chip such as a wafer level chip scale package (WLCSP), and may be electrically connected to the end surface 161 of the first post 16a of the conductive structure 1a of the semiconductor package structure 4b through the solder material 65.

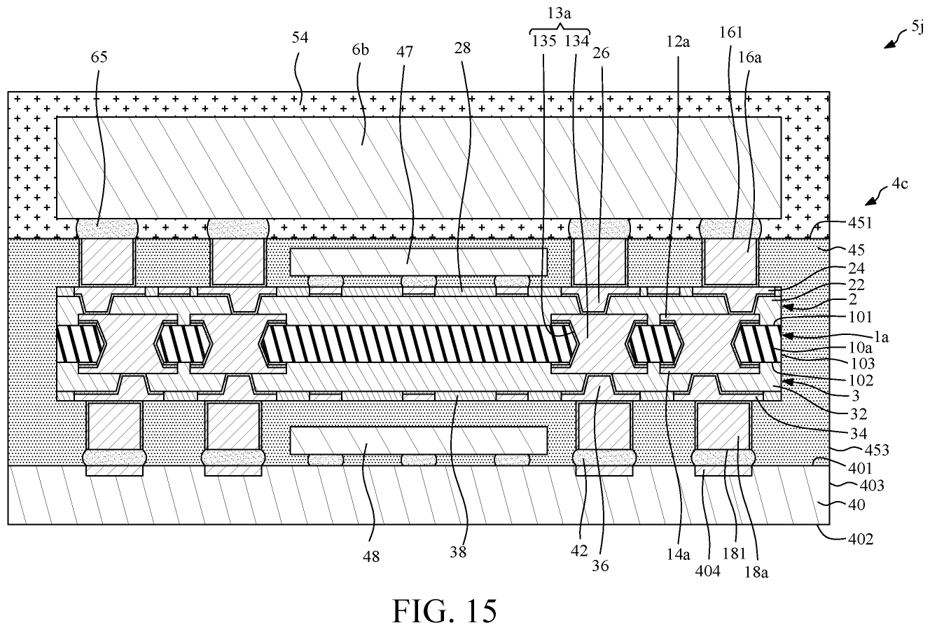

FIG. 15 illustrates a cross-sectional view of a semiconductor package structure 5j according to some embodiments of the present disclosure. The semiconductor package structure 5j includes a semiconductor package structure 4c (i.e., a bottom package structure), a top element 6b and a top encapsulant 54. The semiconductor package structure 4c of FIG. 15 is similar to the semiconductor package structure 4a of FIG. 4, except that the lower electronic device 48 may be electrically connected to the substrate 40 through flip-chip bonding. The top element 6b of FIG. 15 may be disposed on and attached to the first post 16a of the conductive structure 1a of the semiconductor package structure 4c. In some embodiments, the top element 6b may be electrically connected to the end surface 161 of the first post 16a of the conductive structure 1a of the semiconductor package structure 4c through the solder material 65. The top encapsulant 54 (e.g., a molding compound) is disposed on the first surface 451 of the encapsulant 45 to cover and encapsulate the top element 6b.

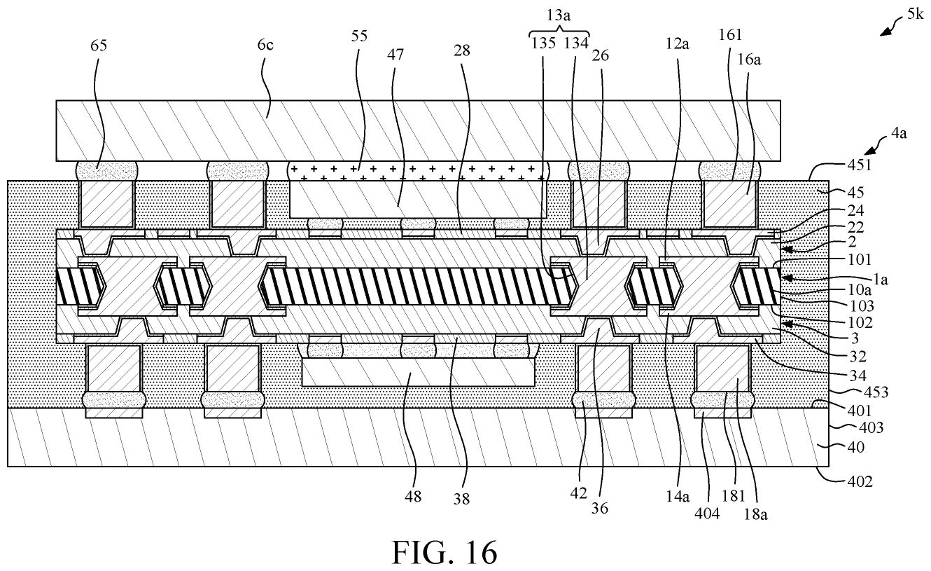

FIG. 16 illustrates a cross-sectional view of a semiconductor package structure 5k according to some embodiments of the present disclosure. The semiconductor package structure 5k includes a semiconductor package structure 4a, a top element 6c and a thermally conductive material 55. The semiconductor package structure 4a of FIG. 16 is similar to or the same as the semiconductor package structure 4a of FIG. 4. The top element 6c of FIG. 16 may be a heat sink, and may be disposed on and attached to the end surface 161 of the first post 16a of the conductive structure 1a of the semiconductor package structure 4a through the solder material 65. The thermally conductive material 55 is interposed between the top element 6c and the upper electronic device 47. The thermally conductive material 55 may be a thermal interface material (TIM) for dissipating the heat generated by the upper electronic device 47 to the top element 6c.

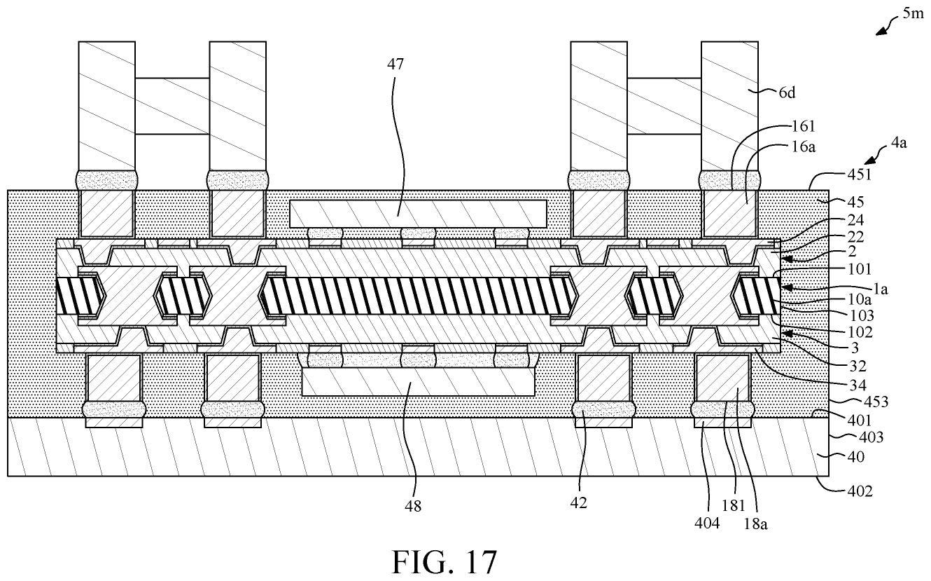

FIG. 17 illustrates a cross-sectional view of a semiconductor package structure 5m according to some embodiments of the present disclosure. The semiconductor package structure 5m includes a semiconductor package structure 4a and at least one top element 6d. The semiconductor package structure 4a of FIG. 17 is similar to or the same as the semiconductor package structure 4a of FIG. 4. The top element 6d of FIG. 17 may be a passive component such as a capacitor, and may be disposed on and attached to the end surface 161 of the first post 16a of the conductive structure 1a of the semiconductor package structure 4a.

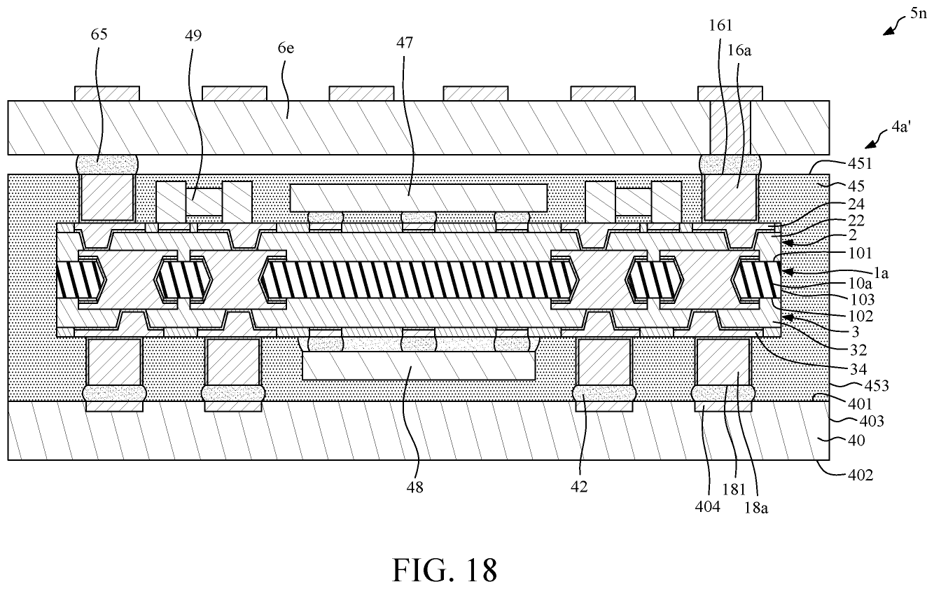

FIG. 18 illustrates a cross-sectional view of a semiconductor package structure 5n according to some embodiments of the present disclosure. The semiconductor package structure 5n includes a semiconductor package structure 4a′ and at least one top element 6e. The semiconductor package structure 4a′ of FIG. 18 is similar to or the same as the semiconductor package structure 4a′ of FIG. 10. The top element 6e of FIG. 18 may be an antenna board, and may be disposed on and attached to the end surface 161 of the first post 16a of the conductive structure 1a of the semiconductor package structure 4a′.

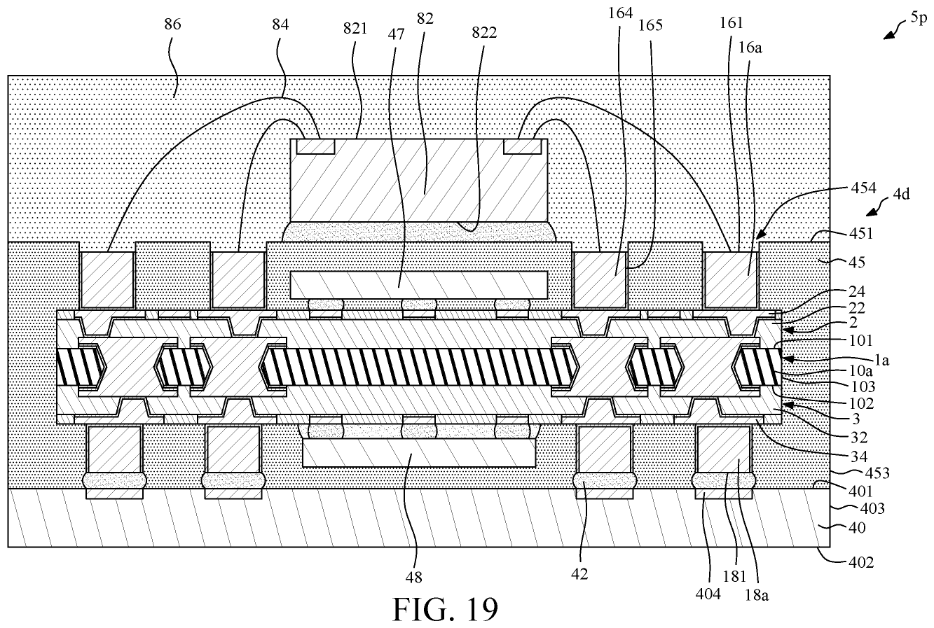

FIG. 19 illustrates a cross-sectional view of a semiconductor package structure 5p according to some embodiments of the present disclosure. The semiconductor package structure 5p includes a semiconductor package structure 4d (i.e., a bottom package structure), a top element 82 and a top encapsulant 86. The semiconductor package structure 4d of FIG. 19 is similar to the semiconductor package structure 4a of FIG. 4, except that the encapsulant 45 defines a plurality of openings 454 recessed from the first surface 451 of the encapsulant 45 to expose the end surfaces 161 of the first post 16a of the conductive structure 1a. The top element 82 may be a semiconductor chip or a semiconductor die. A backside surface 822 of the top element 82 may be adhered to or attached to the first surface 451 of the encapsulant 45. An active surface 821 of the top element 82 may be electrically connected to the end surface 161 of the first post 16a of the conductive structure 1a of the semiconductor package structure 4d through the conductive wire 84. The top encapsulant 86 (e.g., a molding compound) is disposed on the first surface 451 of the encapsulant 45 to cover and encapsulate the top element 82 and the conductive wire 84.

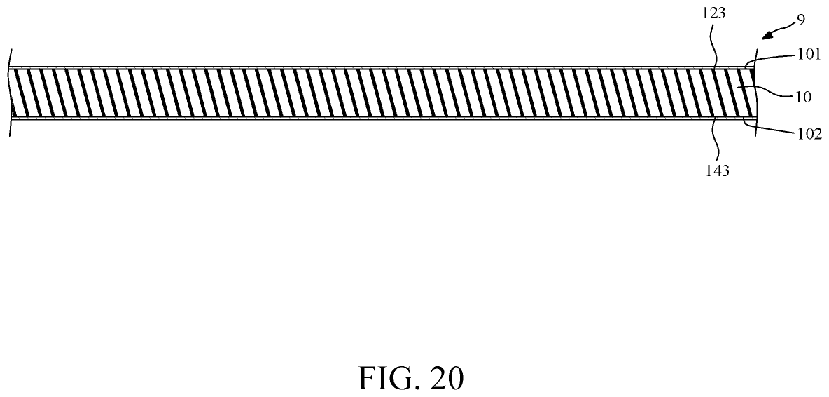

FIG. 20 through FIG. 24 illustrate a method for manufacturing a semiconductor package structure according to some embodiments of the present disclosure. In some embodiments, the method is for manufacturing the semiconductor package structure 4 shown in FIG. 3 and the semiconductor package structure 5 shown in FIG. 5.

Referring to FIG. 20 through FIG. 23, a conductive structure 1 as shown in FIG. 1 is provided. The conductive structure 1 may be manufactured as follows. Referring to FIG. 20, a plate material 9 is provided. The plate material 9 may be a copper-clad laminate (CCL), and may include a main material 10, a base layer 123 (e.g., a copper foil) disposed on the first surface 101 of the main portion 10 and a base layer 143 (e.g., a copper foil) disposed on the second surface 101 of the main portion 10.

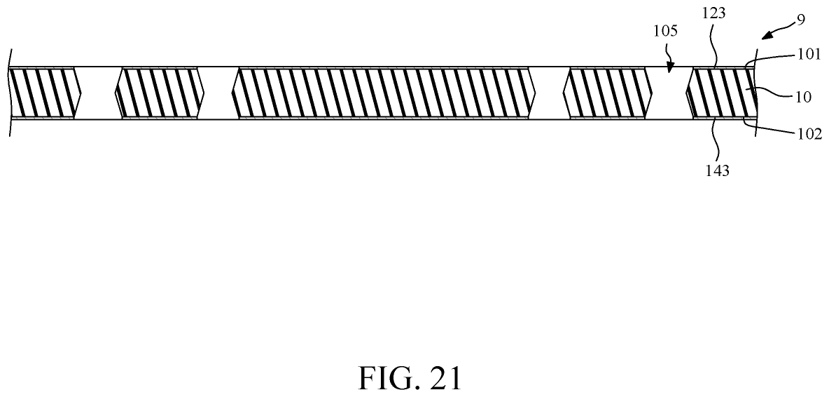

Referring to FIG. 21, a plurality of via holes 105 are formed to extend through the plate material 9. In some embodiments, a cross section of the via hole 105 may be in a shape of sandglass, and may include a neck portion. That is, a width of an upper portion of the via hole 105 and a width of a lower portion of the via hole 105 is greater than a width of a middle portion of the via hole 105. However, in other embodiments, the via hole 105 may be in a shape of a cylinder or a taper.

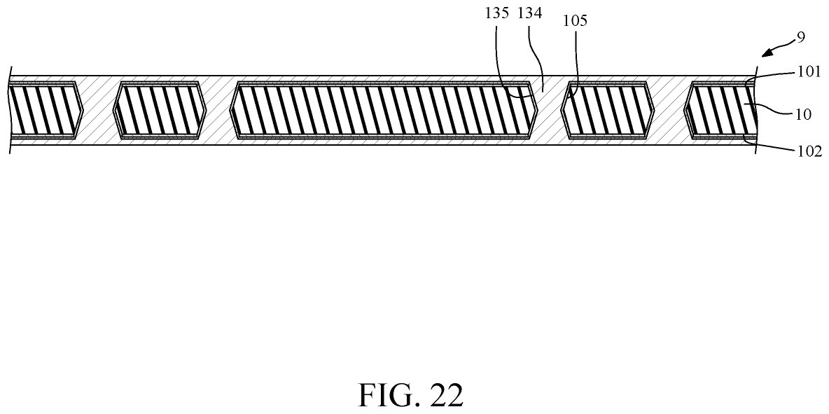

Referring to FIG. 22, a seed layer 135 may be formed on the base layers 123, 143 and in the via holes 105. The seed layer 135 may include a titanium layer and/or a copper layer, and may be formed by chemical vapor deposition (CVD). Then, a conductive material 134 may be formed on the seed layer 135 and may fill the via holes 105. The conductive material 134 may include pure metal such as copper, and may be formed by plating.

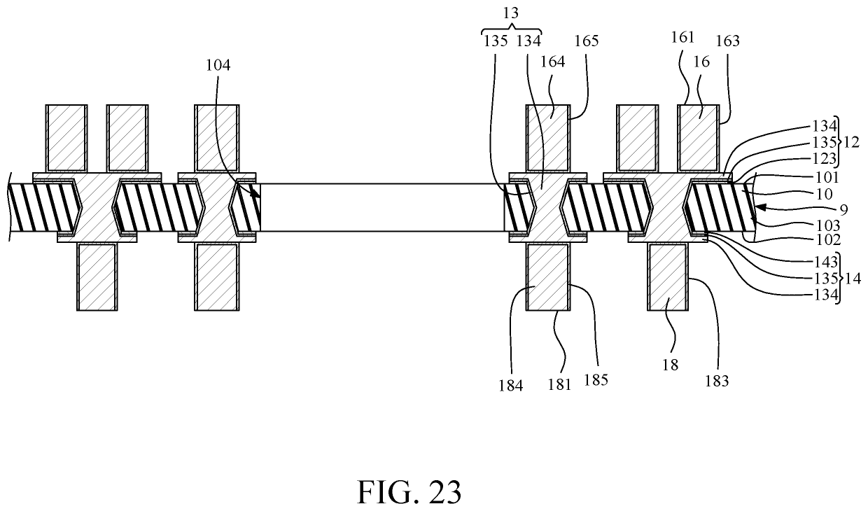

Referring to FIG. 23, the conductive material 134, the seed layer 135 and the base layers 123, 143 are patterned so as to form a first electrical contact 12 on the first surface 101 of the main portion 10, a second electrical contact 14 on the second surface 102 of the main portion 10 and at least one conductive through via 13 in the via hole 105. Then, at least one first post 16 is formed on the first electrical contact 12, and at least one second post 18 is formed on the second electrical contact 14 by, for example, plating. Then, at least one through hole 104 is formed to extend through the plate material 9. Then, the plate material 9 may be singulated to obtain the conductive structure 1 of FIG. 1.

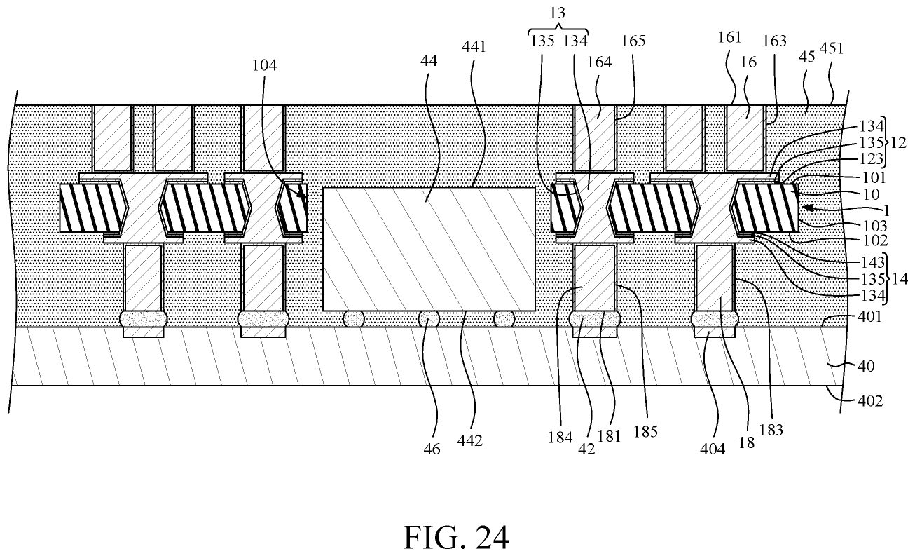

Referring to FIG. 24, the end surfaces 181 of the second posts 18 of the conductive structure 1 may be attached to and electrically connected to the pads 404 of a substrate 40 through a plurality of solder bumps 42. Then, a second surface 442 of an electronic device 44 may be electrically connected to the substrate 40 through the solder materials 46. A portion of the electronic device 44 is located in the through hole 104 of the conductive structure 1. Then, an encapsulant 45 (e.g., a molding compound) may be formed to cover the conductive structure 1, the electronic device 44, the first surface 401 of the substrate 40. Then, a singulation process may be conducted to obtain the semiconductor package structure 4 shown in FIG. 3. Then, a top element 6 is disposed on the first post 16 of the semiconductor package structure 4 to obtain the semiconductor package structure 5 shown in FIG. 5.

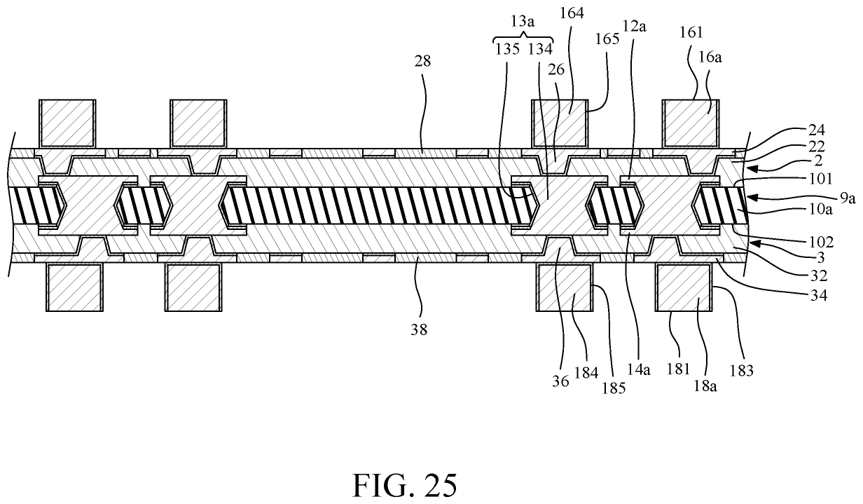

FIG. 25 through FIG. 27 illustrate a method for manufacturing a semiconductor package structure according to some embodiments of the present disclosure. In some embodiments, the method is for manufacturing the semiconductor package structure 4a shown in FIG. 4.

Referring to FIG. 25, a conductive structure 1a as shown in FIG. 2 is provided. The conductive structure 1a may be manufactured as follows. A plate material 9a is provided. The plate material 9a may be a copper-clad laminate (CCL), and may include a main portion 10a. Then, a first electrical contact 12a is formed on the first surface 101 of the main portion 10a, a second electrical contact 14a is formed on the second surface 102 of the main portion 10a and at least one conductive through via 13a is formed to extend through the plate material 9a.

Then, a first redistribution structure 2 may be formed or disposed on the first surface 101 of the main portion 10 and may cover the first electrical contact 12a. A second redistribution structure 3 may be formed or disposed on the second surface 102 of the main portion 10 and may cover the second electrical contact 14a. Then, at least one first post 16a is formed or disposed on the first circuit layer 24 of the first redistribution structure 2 by, for example, plating. At least one second post 18a is formed or disposed on the second circuit layer 34 of the second redistribution structure 3 by, for example, plating. In some embodiments, the plate material 9a may be singulated to obtain the conductive structure 1a of FIG. 2.

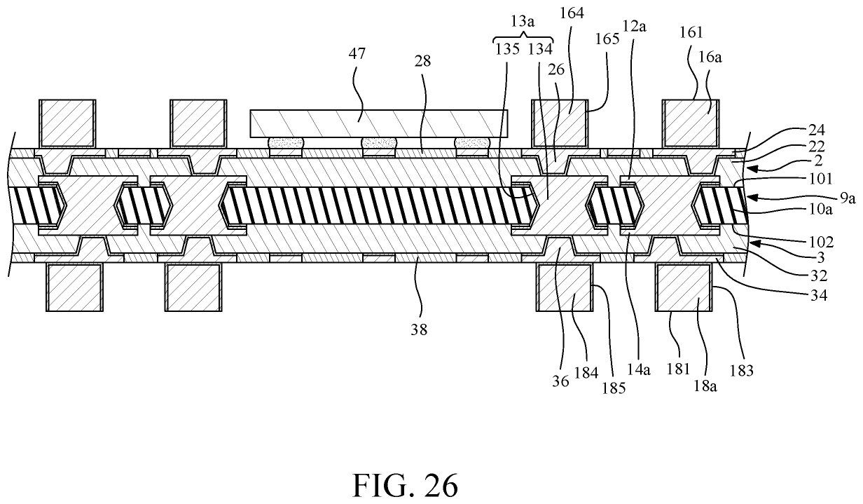

Referring to FIG. 26, an upper electronic device 47 may be attached to and electrically connected to the first circuit layer 24 of the first redistribution structure 2 of the conductive structure 1a through, for example, flip-chip bonding.

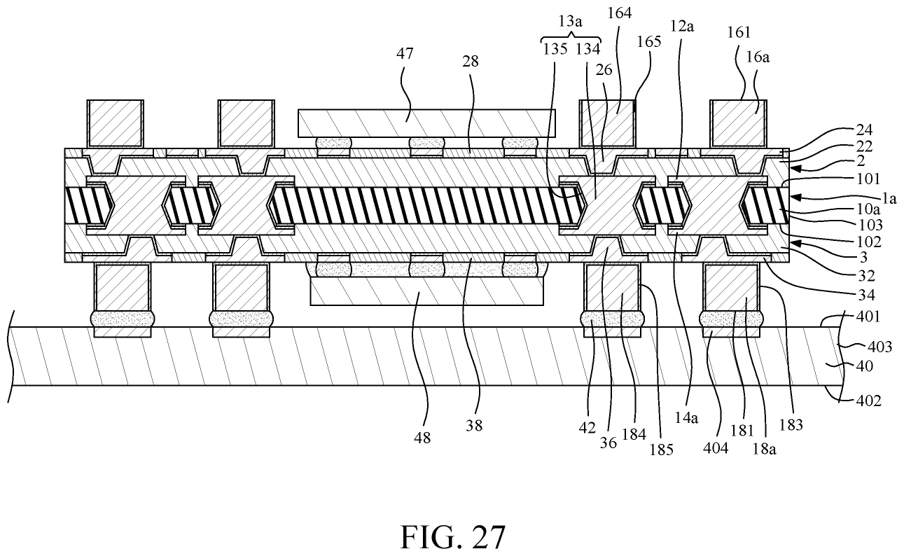

Referring to FIG. 27, a lower electronic device 48 may be attached to and electrically connected to the second circuit layer 34 of the second redistribution structure 3 of the conductive structure 1a through, for example, flip-chip bonding. In some embodiments, the plate material 9a may be singulated to obtain the conductive structure 1a of FIG. 2.

Then, the end surfaces 181 of the second posts 18 of the conductive structure 1 may be attached to and electrically connected to the pads 404 of a substrate 40 through a plurality of solder bumps 42. Then, a second surface 442 of an electronic device 44 may be electrically connected to the substrate 40 through the solder materials 46. A portion of the electronic device 44 is located in the through hole 104 of the conductive structure 1. Then, an encapsulant 45 (e.g., a molding compound) may be formed to cover the conductive structure 1, the electronic device 44, the first surface 401 of the substrate 40. Then, a singulation process may be conducted to obtain the semiconductor package structure 4 shown in FIG. 3. Then, a top element 6 is disposed on the first post 16 of the semiconductor package structure 4 to obtain the semiconductor package structure 5 shown in FIG. 5.

Spatial descriptions, such as “above,” “below,” “up,” “left,” “right,” “down,” “top,” “bottom,” “vertical,” “horizontal,” “side,” “higher,” “lower,” “upper,” “over,” “under,” and so forth, are indicated with respect to the orientation shown in the figures unless otherwise specified. It should be understood that the spatial descriptions used herein are for purposes of illustration only, and that practical implementations of the structures described herein can be spatially arranged in any orientation or manner, provided that the merits of embodiments of this disclosure are not deviated from by such an arrangement.

As used herein, the terms “approximately,” “substantially,” “substantial” and “about” are used to describe and account for small variations. When used in conjunction with an event or circumstance, the terms can refer to instances in which the event or circumstance occurs precisely as well as instances in which the event or circumstance occurs to a close approximation. For example, when used in conjunction with a numerical value, the terms can refer to a range of variation less than or equal to ±10% of that numerical value, such as less than or equal to ±5%, less than or equal to ±4%, less than or equal to ±3%, less than or equal to ±2%, less than or equal to ±1%, less than or equal to ±0.5%, less than or equal to ±0.1%, or less than or equal to ±0.05%. For example, a first numerical value can be deemed to be “substantially” the same or equal to a second numerical value if the first numerical value is within a range of variation of less than or equal to ±10% of the second numerical value, such as less than or equal to ±5%, less than or equal to ±4%, less than or equal to ±3%, less than or equal to ±2%, less than or equal to ±1%, less than or equal to ±0.5%, less than or equal to ±0.1%, or less than or equal to ±0.05%. For example, “substantially” perpendicular can refer to a range of angular variation relative to 90° that is less than or equal to ±10°, such as less than or equal to ±5°, less than or equal to ±4°, less than or equal to ±3°, less than or equal to ±2°, less than or equal to ±1°, less than or equal to ±0.5°, less than or equal to ±0.1°, or less than or equal to ±0.05°.

Two surfaces can be deemed to be coplanar or substantially coplanar if a displacement between the two surfaces is no greater than 5 μm, no greater than 2 μm, no greater than 1 μm, or no greater than 0.5 μm. A surface can be deemed to be substantially flat if a displacement between a highest point and a lowest point of the surface is no greater than 5 μm, no greater than 2 μm, no greater than 1 μm, or no greater than 0.5 μm.

As used herein, the singular terms “a,” “an,” and “the” may include plural referents unless the context clearly dictates otherwise.

As used herein, the terms “conductive,” “electrically conductive” and “electrical conductivity” refer to an ability to transport an electric current. Electrically conductive materials typically indicate those materials that exhibit little or no opposition to the flow of an electric current. One measure of electrical conductivity is Siemens per meter (S/m). Typically, an electrically conductive material is one having a conductivity greater than approximately 10⁴ S/m, such as at least 10⁵ S/m or at least 10⁶ S/m. The electrical conductivity of a material can sometimes vary with temperature. Unless otherwise specified, the electrical conductivity of a material is measured at room temperature.

Additionally, amounts, ratios, and other numerical values are sometimes presented herein in a range format. It is to be understood that such range format is used for convenience and brevity and should be understood flexibly to include numerical values explicitly specified as limits of a range, but also to include all individual numerical values or sub-ranges encompassed within that range as if each numerical value and sub-range is explicitly specified.

While the present disclosure has been described and illustrated with reference to specific embodiments thereof, these descriptions and illustrations are not limiting. It should be understood by those skilled in the art that various changes may be made and equivalents may be substituted without departing from the true spirit and scope of the present disclosure as defined by the appended claims. The illustrations may not be necessarily drawn to scale. There may be distinctions between the artistic renditions in the present disclosure and the actual apparatus due to manufacturing processes and tolerances. There may be other embodiments of the present disclosure which are not specifically illustrated. The specification and drawings are to be regarded as illustrative rather than restrictive. Modifications may be made to adapt a particular situation, material, composition of matter, method, or process to the objective, spirit and scope of the present disclosure. All such modifications are intended to be within the scope of the claims appended hereto. While the methods disclosed herein have been described with reference to particular operations performed in a particular order, it will be understood that these operations may be combined, sub-divided, or re-ordered to form an equivalent method without departing from the teachings of the present disclosure. Accordingly, unless specifically indicated herein, the order and grouping of the operations are not limitations of the present disclosure.

What is claimed is:

1. A conductive structure, comprising:
a main portion having a first surface and a second surface opposite to the first surface;
a first electrical contact disposed adjacent to the first surface of the main portion;
a second electrical contact disposed adjacent to the second surface of the main portion and electrically connected to the first electrical contact;
a first post electrically connected to the first electrical contact; and
a second post electrically connected to the second electrical contact.

2. The conductive structure of claim 1, wherein the main portion defines a through hole extending through the main portion.

3. The conductive structure of claim 1, wherein at least one of the first post and the second post includes a pure material.

4. The conductive structure of claim 3, wherein at least one of the first post and the second post further includes a seed layer contacting the pure material.

5. The conductive structure of claim 1, further comprising a conductive through via extending through the main portion and electrically connecting the first electrical contact and the second electrical contact.

6. The conductive structure of claim 1, wherein a central axis of the first post is shifted from a central axis of the second post.

7. The conductive structure of claim 1, further comprising:
a first redistribution structure disposed on the first surface of the main portion and covering the first electrical contact, wherein the first post is electrically connected to the first electrical contact through the first redistribution structure; and
a second redistribution structure disposed on the second surface of the main portion and covering the second electrical contact, wherein the second post is electrically connected to the second electrical contact through the second redistribution structure.

8. A package structure, comprising:
a substrate;
a conductive structure attached to the substrate, and comprising:
a main portion having a first surface and a second surface opposite to the first surface;
a first electrical contact disposed adjacent to the first surface of the main portion;
a second electrical contact disposed adjacent to the second surface of the main portion and electrically connected to the first electrical contact;
a first post electrically connected to the first electrical contact; and
a second post electrically connected to the second electrical contact and the substrate;
an electronic device electrically connected to the substrate or the conductive structure; and
an encapsulant covering the substrate, the conductive structure and the electronic device.

9. The package structure of claim 8, wherein the second post is attached to the substrate through a solder bump.

10. The package structure of claim 8, wherein the main portion defines a through hole extending through the main portion, the electronic device is attached to the substrate and a portion of the electronic device is located in the through hole.

11. The package structure of claim 8, wherein the first post and the second post are formed by plating.

12. The package structure of claim 8, wherein a peripheral side surface of the first post and a peripheral side surface of the second post are perpendicular to the first surface and the second surface of the main portion, respectively.

13. The package structure of claim 8, wherein the conductive structure further comprises:
a first redistribution structure disposed on the first surface of the main portion and covering the first electrical contact, wherein the first post is electrically connected to the first electrical contact through the first redistribution structure; and
a second redistribution structure disposed on the second surface of the main portion and covering the second electrical contact, wherein the second post is electrically connected to the second electrical contact through the second redistribution structure;
wherein the electronic device is attached to and electrically connected to the first redistribution structure or the second redistribution structure.

14. The package structure of claim 8, further comprising a top element disposed on the first post of the conductive structure.

15. The package structure of claim 14, wherein the top element includes a package, a module, a system-in-package (SiP), a semiconductor chip, a semiconductor die, a heat sink, a passive component and an antenna.

16. A method for manufacturing a package structure, comprising:
(a) providing a conductive structure, wherein the conductive structure comprises a main portion, a first post and a second post, the first post is disposed adjacent to a first surface of the main portion, the second post is disposed adjacent to a second surface of the main portion and electrically connected to the first post;
(b) electrically connecting the second post to a substrate;
(c) electrically connecting an electronic device to the substrate or the conductive structure; and
(d) forming an encapsulant to cover the substrate, the conductive structure and the electronic device.

17. The method of claim 16, wherein in (a), the first post and the second post are formed on the main portion by plating.

18. The method of claim 16, wherein in (b), the second post is electrically connected to the substrate through a solder bump.

19. The method of claim 16, further comprising:
(e) disposing a top element on the first post.

20. The method of claim 19, wherein the top element includes a package, a module, a system-in-package (SiP), a semiconductor chip, a semiconductor die, a heat sink, a passive component and an antenna.
